(19) United States
(12) Patent Application Publication
(10) Pub. No.: US 2026/0107836 A1
(43) Pub. Date: Apr. 16, 2026

(54) SEMICONDUCTOR PACKAGE WITH VERTICAL CONDUCTIVE STRUCTURE

(71) Applicant: SAMSUNG ELECTRONICS CO., LTD., Suwon-si (KR)

(72) Inventors: Eunkyeong PARK, Suwon-si (KR); Sang Sub Song, Suwon-si (KR); Seokbeom Yong, Suwon-si (KR)

(73) Assignee: SAMSUNG ELECTRONICS CO., LTD., Suwon-si (KR)

(21) Appl. No.: 19/204,942

(22) Filed: May 12, 2025

(30) Foreign Application Priority Data
Oct. 15, 2024 (KR) 10-2024-0140398

(51) Int. Cl. H01L 23/00; H01L 25/04; H01L 25/16; H10B 80/00

(52) U.S. Cl. CPC H10W 90/00; H10B 80/00; H10W 72/252; H10W 72/9445; H10W 90/20; H10W 90/24; H10W 90/724

(57) ABSTRACT

A semiconductor package includes a substrate, a first semiconductor chip on the substrate, and a second semiconductor chip on the first semiconductor chip. The second semiconductor chip is offset from the first semiconductor chip in a first direction parallel to a top surface of the substrate. The first semiconductor chip includes a plurality of first chip pads disposed to form a plurality of first columns. A first edge column of the plurality of first columns is adjacent to a first side surface of the first semiconductor chip and to a previous column of the plurality of first columns. The second semiconductor chip includes a plurality of second chip pads disposed to form a plurality of second columns. A second edge column of the plurality of second columns is adjacent to the first side surface of the first semiconductor chip and to a next column of the plurality of second columns.

### CROSS-REFERENCE TO RELATED APPLICATIONS

This application claims benefit of priority under 35 U.S.C. § 119 to Korean Patent Application No. 10-2024-0140398, filed on October 15, 2024, in the Korean Intellectual Property Office, the disclosure of which is incorporated by reference herein in its entirety.

### BACKGROUND

### 1. Field

The present disclosure relates generally to semiconductor packages, and more particularly to, a semiconductor package with a vertical conductive structure and a manufacturing method thereof.

### 2. Description of Related Art

A semiconductor package may be configured to use a semiconductor chip as a part of an electronic product. In general, a semiconductor package may include a printed circuit board (PCB) and a semiconductor chip, which may be mounted on the PCB and may be electrically connected to the PCB using bonding wires and/or bumps. Recent developments in an electronics industry may be directed towards research for potentially improving reliability of semiconductor packages and/or reducing a size of the semiconductor packages.

### SUMMARY

One or more example embodiments of the present disclosure provide a semiconductor package, which may be configured to reduce a cross-talk between vertical conductive structures connected to chip signal pads of a semiconductor chip and may have an improve reliability, when compared to related semiconductor chips.

According to an aspect of the present disclosure, a semiconductor package includes a substrate, a first semiconductor chip on the substrate, and a second semiconductor chip on the first semiconductor chip. The second semiconductor chip is offset from the first semiconductor chip in a first direction parallel to a top surface of the substrate. The first semiconductor chip includes a plurality of first chip pads disposed to form a plurality of first columns. A first edge column of the plurality of first columns is adjacent to a first side surface of the first semiconductor chip and to a previous column of the plurality of first columns. The second semiconductor chip includes a plurality of second chip pads disposed to form a plurality of second columns. A second edge column of the plurality of second columns is adjacent to the first side surface of the first semiconductor chip and to a next column of the plurality of second columns. One or more first chip pads of the first edge column and the previous column include a plurality of first chip signal pads. One or more second chip pads of the second edge column and the next column include a plurality of second chip signal pads. A first number of first chip signal pads of the first edge column is greater than a second number of first chip signal pads of the previous column. A third number of second chip signal pads of the second edge column is greater than a fourth number of second chip signal pads of the next column.

According to an aspect of the present disclosure, a semiconductor package includes a substrate, a first semiconductor chip on the substrate, a second semiconductor chip on the first semiconductor chip and offset from the first semiconductor chip in a first direction parallel to a top surface of the substrate, a plurality of first vertical conductive structures between the first semiconductor chip and the substrate, and a plurality of second vertical conductive structures between the second semiconductor chip and the substrate. The first semiconductor chip includes a plurality of first chip pads, disposed in the first direction to form a plurality of N first columns. N is a positive integer greater than one. The second semiconductor chip includes a plurality of second chip pads, disposed in the first direction to form a plurality of N second columns. Each of a first column and an N-th column of the plurality of N first columns includes a first number of chip signal pads that is greater than a second number of first chip pads included by each of remaining second to (N–1)-th columns of the plurality of N first columns. Each of a first column and an N-th column of the plurality of N second columns includes a third number of chip signal pads that is greater than a fourth number of second chip pads included by each of remaining second to (N–1)-th columns of the plurality of N second columns. The plurality of first vertical conductive structures are coupled with the plurality of first chip pads, respectively. The plurality of second vertical conductive structures are coupled with the plurality of second chip pads, respectively.

According to an aspect of the present disclosure, a semiconductor package includes a first semiconductor package, and a second semiconductor package on the first semiconductor package. The second semiconductor package includes a connection substrate, a semiconductor chip stack vertically spaced apart from the connection substrate, a plurality of vertical conductive structures between the semiconductor chip stack and the connection substrate, and a mold layer at least partially covering the connection substrate, the semiconductor chip stack, and the plurality of vertical conductive structures. The semiconductor chip stack includes a plurality of semiconductor chips stacked in an offset manner, in a first direction parallel to a top surface of the connection substrate. Each of the plurality of semiconductor chips includes a plurality of chip pads coupled with the plurality of vertical conductive structures. The plurality of chip pads includes a plurality of chip signal pads. The plurality of chip pads are disposed in the first direction to form a plurality of N columns. N is a positive integer greater than one. A number of chip signal pads in a first column of the plurality of N columns is greater than a number of chip signal pads in a second column of the plurality of N columns. A number of chip signal pads in an N-th column of the plurality of N columns is greater than a number of chip signal pads in an (N–1)-th column of the plurality of N columns.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a sectional view illustrating a semiconductor package, according to an embodiment of the present disclosure;

FIG. 2 is a plan view illustrating active surfaces of the first and second semiconductor chips, according to an embodiment of the present disclosure;

FIG. 3 is an enlarged view illustrating a portion EG1 of FIG. 1, according to an embodiment of the present disclosure;

FIG. 4 is a plan view illustrating a top surface of a connection substrate, according to an embodiment of the present disclosure;

FIG. 5 is a plan view illustrating active surfaces of the first and second semiconductor chips, according to an embodiment of the present disclosure;

FIG. 6 is a plan view illustrating a top surface of a connection substrate, according to an embodiment of the present disclosure;

FIG. 7 is a sectional view illustrating a semiconductor package, according to an embodiment of the present disclosure;

FIGS. 8 to 10 are sectional views illustrating a process of fabricating a semiconductor package, according to an embodiment of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element or layer is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or layer or may include an entirety of the other element or layer. Similarly, when an element or layer is referred to as “penetrating” another element or layer, the element or layer may penetrate at least a portion of the other element or layer, where the portion may include a fraction of the other element or layer or may include an entire dimension (e.g., length, width, depth) of the other element or layer.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more.” Where only one item is intended, the term “one” or similar language is used. For example, the term “a semiconductor device” may refer to either a single semiconductor device or multiple semiconductor devices. When a semiconductor device is described as carrying out an operation and the semiconductor device is referred to perform an additional operation, the multiple operations may be executed by either a single semiconductor device or any one or a combination of multiple semiconductor devices.

Hereinafter, various embodiments of the present disclosure are described with reference to the accompanying drawings.

As used herein, the term adjacent as applied to a first column and a second column may indicate that no other columns are interposed between them, and that the first column and the second column may be either directly neighboring or in close proximity to each other. The term may equally apply to cases where other columns are described as being adjacent to one another.

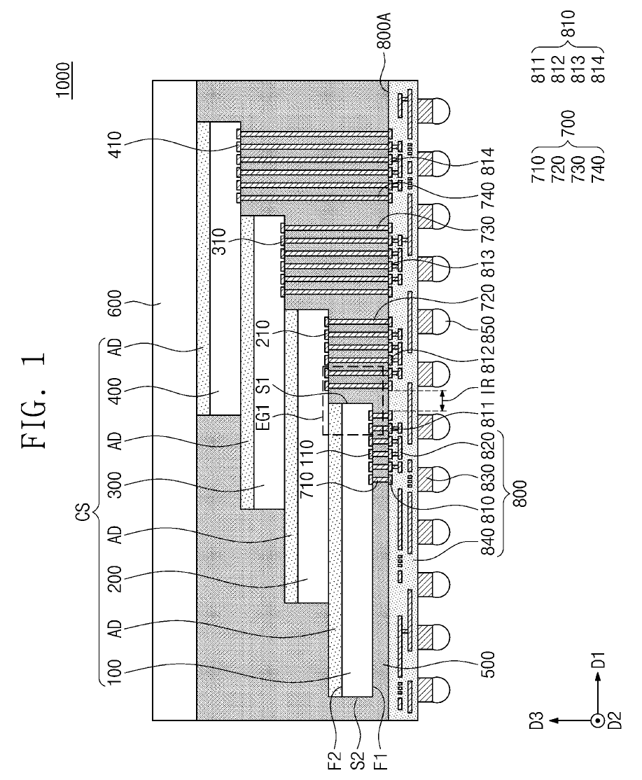

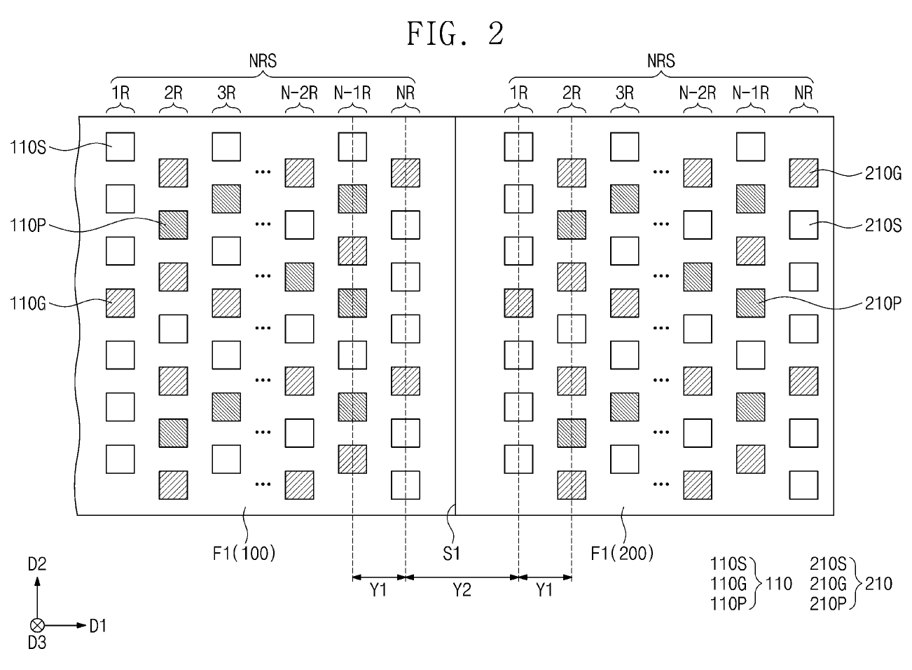

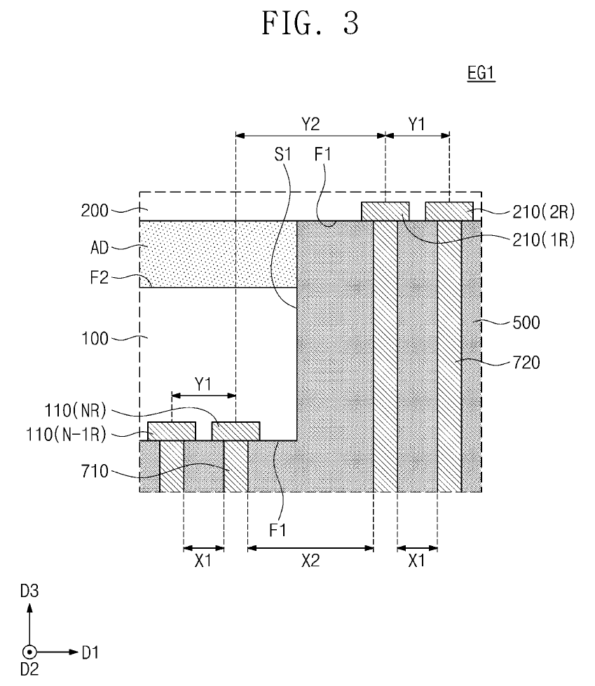

FIG. 1 is a sectional view illustrating a semiconductor package, according to an embodiment of the present disclosure. FIG. 2 is a plan view illustrating active surfaces of the first and second semiconductor chips, according to an embodiment of the present disclosure. FIG. 3 is an enlarged view illustrating a portion EG1 of FIG. 1, according to an embodiment of the present disclosure.

Referring to FIG. 1, a semiconductor package 1000 may include a semiconductor chip stack CS, a connection substrate 800, a mold layer 500, a plurality of vertical conductive structures 700, and a supporting substrate 600.

As used herein, a first direction D1 may refer to a direction parallel to a top surface of the supporting substrate 600. A second direction D2 may refer to a direction parallel to the top surface of the supporting substrate 600 and may be perpendicular to the first direction D1. A third direction D3 may refer to a direction perpendicular to the top surface of the supporting substrate 600. The first and second directions D1 and D2 may be directions that are parallel to a top surface 800A of the connection substrate 800. The third direction D3 may be a direction perpendicular to the top surface 800A of the connection substrate 800.

The semiconductor chip stack CS may include a plurality of semiconductor chips, which may be stacked in an offset manner, and a plurality of adhesive layers AD, which may be interposed therebetween. The plurality of semiconductor chips may include a first semiconductor chip 100, a second semiconductor chip 200, a third semiconductor chip 300, and a fourth semiconductor chip 400. However, the present disclosure is not limited in this regard, and the number of semiconductor chips in the plurality of first to fourth semiconductor chips 100 to 400 included in the semiconductor chip stack CS may vary. For example, the number of semiconductor chips in the plurality of first to fourth semiconductor chips 100 to 400 may be smaller (e.g., less than four (4)) or may be larger (e.g., greater than four (4)).

As used herein, the expression “the plurality of first to fourth semiconductor chips 100 to 400 are stacked in an offset manner” may indicate that semiconductor chips (e.g., the first semiconductor chip 100 and the second semiconductor chip 200), which may be adjacent to each other in the third direction D3, may be stacked in a diagonal direction, that the semiconductor chips (e.g., the first semiconductor chip 100 and the second semiconductor chip 200) may be disposed to be adjacent to each other in the first direction D1 and the third direction D3, or that side surfaces of the semiconductor chips (e.g., the first semiconductor chip 100 and the second semiconductor chip 200), which may be adjacent to each other in the third direction D3, may not be overlapped with each other in the third direction D3.

The plurality of first to fourth semiconductor chips 100 to 400 may be and/or may include memory chips. For example, each semiconductor chip of the plurality of first to fourth semiconductor chips 100 to 400 may be and/or may include, but not be limited to, at least one of a dynamic random access memory (DRAM) device, a static random access memory (SRAM), a NAND flash memory device, or the like. As another example, each semiconductor chip of the plurality of first to fourth semiconductor chips 100 to 400 may be and/or may include, but not be limited to, a DRAM device having the same integrated circuit.

Each semiconductor chip of the plurality of first to fourth semiconductor chips 100 to 400 may include a lower surface F1 and an upper surface F2, which may be opposite to each other. The lower surface F1 may be an active surface, on which an integrated circuit is disposed. However, the present disclosure is not limited in this regard. For example, in an embodiment, the active surface may be the upper surface F2.

The first semiconductor chip 100 may include a plurality of first chip pads 110 disposed on a first lower surface F1. The second semiconductor chip 200 may include a plurality of second chip pads 210 disposed on a second lower surface F1. The third semiconductor chip 300 may include a plurality of third chip pads 310 disposed on a third lower surface F1. The fourth semiconductor chip 400 may include a plurality of fourth chip pads 410 disposed on a fourth lower surface F1. For example, the plurality of first chip pads 110 may be disposed on the first lower surface F1 of the first semiconductor chip 100 and near an edge of the first lower surface F1. The plurality of first chip pads 110 may be disposed to be close to one side surface (e.g., a first side surface S1) of two (2) opposite side surfaces of the first semiconductor chip 100 and to be far from the other side surface (e.g., the second side surface S2). The disposition of the plurality of second chip pads 210 relative to the second semiconductor chip 200, the disposition of the plurality of third chip pads 310 relative to the third semiconductor chip 300, and the disposition of the plurality of fourth chip pads 410 relative to the fourth semiconductor chip 400 may be substantially similar and/or the same as the disposition of the plurality of first chip pads 110 relative to the first semiconductor chip 100.

Each adhesive layer of the plurality of adhesive layers AD may be formed on each upper surface F2 of the plurality of first to fourth semiconductor chips 100 to 400. For example, a first adhesive layer of the plurality of adhesive layers AD may be interposed between the first upper surface F2 of the first semiconductor chip 100 therebelow and the second lower surface F1 of the second semiconductor chip 200 thereon to bond the first semiconductor chip 100 and the second semiconductor chip 200 together. The plurality of second chip pads 210 of the second semiconductor chip 200 may be exposed from the first adhesive layer of the plurality of adhesive layers AD. Similarly, the plurality of third chip pads 310 and the plurality of fourth chip pads 410 may be exposed from the plurality of adhesive layers AD.

Each adhesive layer of the plurality of adhesive layers AD may be and/or may include a die attach film (DAF). For example, each adhesive layer of the plurality of adhesive layers AD may include, but not be limited to, at least one of polymer materials (e.g., epoxy resins, polyimide, and acrylate).

The connection substrate 800 may be spaced apart from the semiconductor chip stack CS in the third direction D3. For example, the connection substrate 800 may be and/or may include a redistribution layer. The connection substrate 800 may include an upper pad 810, a redistribution pattern 820, a lower pad 830, and an insulating layer 840. As used herein, the upper pad 810 may be referred to as a landing pad or a substrate pad. The upper pad 810 and the lower pad 830 may be exposed from the insulating layer 840. The redistribution pattern 820 may be provided in the insulating layer 840. The redistribution pattern 820 may electrically connect the upper pad 810 to the lower pad 830. The upper pad 810 may be in contact with at least one of the plurality of vertical conductive structures 700.

A plurality of connection terminals 850 may be disposed on the lower pad 830. The plurality of connection terminals 850 may be and/or may include, for example, bumps and/or solder balls. At least one connection terminal of the plurality of connection terminals 850 may be placed at a position spaced apart from the semiconductor chip stack CS in a diagonal direction. At least one connection terminal of the plurality of connection terminals 850 may not be overlapped with the semiconductor chip stack CS in the third direction D3. That is, the semiconductor package 1000 may be and/or may include, for example, a fan-out package.

Each of the upper pad 810, the redistribution pattern 820, and the lower pad 830 may be formed of and/or may include at least one of metallic materials. For example, the upper pad 810, the redistribution pattern 820, and the lower pad 830 may be formed of and/or may include, but not be limited to, at least one of metallic materials (e.g., copper (Cu)). The insulating layer 840 may be formed of and/or may include a photoimageable insulating material (e.g., a photoimageable dielectric (PID) material). The photoimageable insulating material may include, but not be limited to, a polymer material (e.g., polyimide (PI) or benzocyclobutene (BCB)).

The plurality of vertical conductive structures 700 may be interposed between each semiconductor chip of the plurality of first to fourth semiconductor chips 100 to 400 and the connection substrate 800. For example, the plurality of vertical conductive structures 700 may include a plurality of first vertical conductive structures 710 interposed between the first semiconductor chip 100 and the connection substrate 800, a plurality of second vertical conductive structures 720 interposed between the second semiconductor chip 200 and the connection substrate 800, a plurality of third vertical conductive structures 730 interposed between the third semiconductor chip 300 and the connection substrate 800, and a plurality of fourth vertical conductive structures 740 interposed between the fourth semiconductor chip 400 and the connection substrate 800.

Each vertical conductive structure of the plurality of vertical conductive structures 700 may be and/or may include, for example, a metal wire. The metal wire may be formed of and/or may include, but not be limited to, at least one of gold (Au), copper (Cu), palladium (Pd), or the like. Alternatively or additionally, each vertical conductive structure of the plurality of vertical conductive structures 700 may include a seed pattern and a metal pillar on the seed pattern. For example, the seed pattern may be formed of and/or may include copper (Cu)/titanium (Ti). As another example, the metal pillar may be formed of and/or may include copper (Cu). That is, one end of the plurality of first vertical conductive structures 710 may be in contact with the upper pad 810 of the connection substrate 800, and another end may be in contact with the plurality of first chip pads 110. The pluralities of second to fourth vertical conductive structures 720 to 740 may include first ends that may be in contact with the upper pads 810 of the connection substrate 800, respectively. The pluralities of second to fourth vertical conductive structures 720 to 740 may further include second ends that may be in contact with the pluralities of second to fourth chip pads 210 to 410, respectively. Each vertical conductive structure of the plurality of vertical conductive structures 700 may be extended in the third direction D3.

The mold layer 500 may cover the lower surfaces F1 and the side surfaces (e.g., the first side surfaces S1 and the second side surfaces S2) of the plurality of first to fourth semiconductor chips 100 to 400, the top and side surfaces of the plurality of adhesive layers AD, and the side surfaces of the plurality of vertical conductive structures 700 may be exposed. The mold layer 500 may be formed of and/or may include, but not be limited to, for example, an insulating resin (e.g., an epoxy molding compound (EMC)).

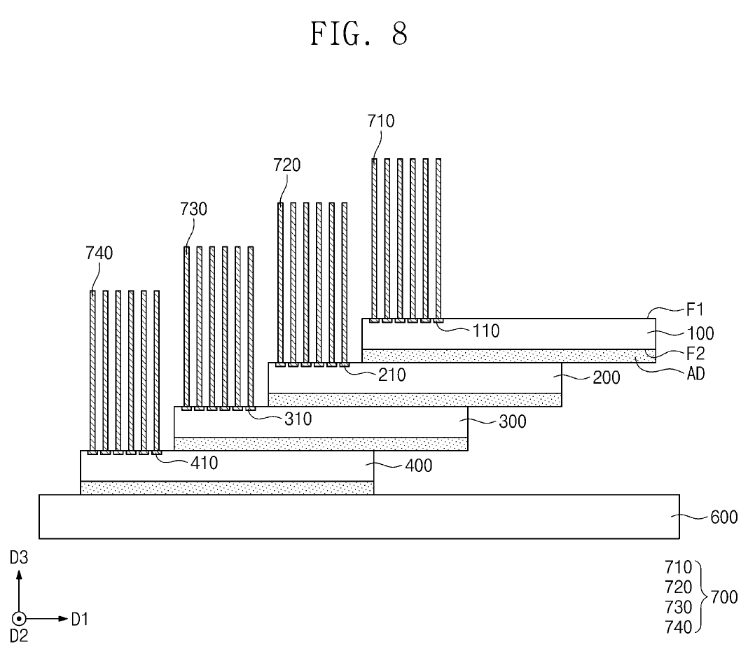

The supporting substrate 600 may be disposed on the uppermost one of the semiconductor chip of the semiconductor chip stack CS (e.g., the fourth semiconductor chip 400). The fourth semiconductor chip 400 may be coupled to the supporting substrate 600 through at least one adhesive layer of the plurality of adhesive layers AD disposed on the fourth upper surface F2 of the fourth semiconductor chip 400. The supporting substrate 600 may be and/or may include, but not be limited to, at least one of a semiconductor substrate (e.g., a silicon (Si) substrate), a glass substrate, a metal substrate, a polymer substrate, or the like. The supporting substrate 600 may be and/or may include a substrate, on which the semiconductor chip stack CS may be disposed, and which may be used to support the semiconductor chip stack CS, as described with reference to FIG. 8. In addition, the supporting substrate 600 may be used as a heat-dissipation substrate for exhausting heat, which may be generated in the semiconductor chip stack CS.

Referring to FIGS. 1 and 2, the plurality of first chip pads 110 may be arranged on the first lower surface F1 of the first semiconductor chip 100 to form N columns NRS (e.g., a first column 1R, a second column 2R, a third column 3R, to an (N–2)-th column N-2R, an (N–1)-th column N-1R, and an N-th column NR, where N is a positive integer greater than one (1)) in the first direction D1. The plurality of first chip pads 110 may be arranged in the first direction D1 and in a zigzag shape. For example, a first chip pad of the plurality of first chip pads 110 in each column may be disposed at a position that may be offset from another first chip pad of the plurality of first chip pads 110, which is included in another column adjacent thereto, in the second direction D2. As another example, the plurality of second chip pads 210 may be arranged on the second lower surface F1 of the second semiconductor chip 200, the plurality of third chip pads 310 may be arranged on the third lower surface F1 of the third semiconductor chip 300, and the plurality of fourth chip pads 410 may be arranged on the fourth lower surface F1 of the fourth semiconductor chip 400 to respectively form the N columns NRS in the first direction D1.

For example, if the N columns NRS are classified based on a distance from the first side surface S1, the column farthest from the first side surface S1 may be the first column 1R, while the column closest to the first side surface S1 may be the last column NR or the N-th column NR. The first column 1R may be referred to as an inner edge column 1R, and the N-th column NR may be referred to as an outer edge column. As used herein, the term inner region may refer to a region close to the center of the first semiconductor chip 100, and the term outer region may refer to a region close to the first semiconductor chip 100.

The plurality of first chip pads 110 may include a plurality of first chip signal pads 110S, a plurality of first chip power pads 110P, and a plurality of first chip ground pads 110G. The plurality of first chip pads 110 in the first column 1R and the plurality of first chip pads 110 in the last column NR may include more first chip signal pads 110S, when compared with the plurality of first chip pads 110 in each of the second to (N–1)-th remaining columns 2R to N-1R. For example, the number of the first chip signal pads 110S in the first column 1R may be greater than the number of the first chip signal pads 110S in the second column 2R. As another example, the number of the first chip signal pads 110S in the last column NR may be greater than the number of the first chip signal pads 110S in the (N–1)-th column N-1R.

The plurality of first chip pads 110 in the second column 2R and the plurality of first chip pads 110 in the (N–1)-th column N-1R may include more first chip ground pads 110G, compared with the plurality of first chip pads 110 in each of the remaining columns (e.g., the first column 1R, the last column NR, and the third to (N–2)-th columns 3R to N-2R). For example, the number of the first chip ground pads 110G in the second column 2R may be greater than the number of the first chip ground pads 110G in the first or third column 1R or 3R. As another example, the number of the first chip ground pads 110G in the second-to-last column N-1R may be greater than the number of the first chip ground pads 110G in its previous column N-2R or the last column NR.

The plurality of second chip pads 210, the plurality of third chip pads 310, and the plurality of fourth chip pads 410 may be disposed to have a substantially similar and/or the same disposition or arrangement as the plurality of first chip pads 110. For example, the plurality of second chip pads 210 may include a plurality of second chip signal pads 210S, a plurality of second chip power pads 210P, and a plurality of second chip ground pads 210G. The plurality of second chip pads 210 in the first column 1R and the plurality of second chip pads 210 in the last column NR may include more second chip signal pads 210S, compared with the plurality of second chip pads 210 in each of the second to (N–1)-th remaining columns 2R to N-1R. The plurality of second chip pads 210 in the second column 2R and the plurality of second chip pads 210 in the (N–1)-th column N-1R may include more second chip ground pads 210G, compared with the plurality of second chip pads 210 in each of the remaining columns (e.g., the first column 1R, the last column, NR, and the third to (N–2)-th columns 3R to N-2R).

A first pitch Y1 between the plurality of first chip pads 110 of the first semiconductor chip 100 in columns adjacent to each other in the first direction D1 may be smaller than a second pitch Y2 between the plurality of first chip pads 110 of the last column NR of the first semiconductor chip 100 and the second chip pads 210 of the first column 1R of the second semiconductor chip 200 (e.g., Y2 > Y1). For example, the second pitch Y2 may be more than twice as large as the first pitch Y1 (e.g., Y2 > 2 × Y1).

Referring to FIG. 3, the plurality of first vertical conductive structures 710, which may be adjacent to each other in the first direction D1, may be disposed on the plurality of first chip pads 110 in columns adjacent to each other in the first direction D1.

A first distance X1 between adjacent ones of the plurality of first vertical conductive structures 710 may be smaller than a second distance X2 between the plurality of first vertical conductive structures 710, which is adjacent to the first side surface S1 of the first semiconductor chip 100, and the plurality of second vertical conductive structures 720, which is adjacent to the first side surface S1 of the second semiconductor chip 200. That is, the second distance X2 may be larger than the first distance X1 (e.g., X2 > X1). For example, the second distance X2 may be more than twice as large as the first distance X1 (e.g., X2 > 2 × X1).

According to an embodiment of the present disclosure, by optimizing the disposition of the chip signal pads and the chip ground pads in the offset-stacked semiconductor chips, it may be possible to reduce a cross-talk between the vertical conductive structures connected to the chip signal pads. For example, the number of the chip signal pads may be greater in the first and last columns of each semiconductor chip than in other columns. The chip signal pads may be less disposed in a center one of the columns. In the case where the chip signal pads are disposed in outer columns, not in the center one of the columns, it may be possible to reduce the cross-talk between the vertical conductive structures, which may be connected to the chip signal pads of two adjacent columns. In addition, the chip ground pads may be more disposed in the second column and the second-to-last column. It may be possible to reduce the cross-talk between the vertical conductive structures connected to the chip signal pads of the first column and the vertical conductive structures connected to the chip signal pads of the second column and the cross-talk between the vertical conductive structures connected to the chip signal pads of the last column and the vertical conductive structures connected to the chip signal pads of the second-to-last column. Even when the chip signal pad in the last column of the first semiconductor chip is adjacent to the chip signal pad in the first column of the second semiconductor chip, since a distance between the chip signal pads may be more than twice as large as the pitch of the columns, it may be possible to more effectively reduce a signal interference issue, when compared to a related semiconductor package. As a result, a cross-talk issue of the semiconductor package may be reduced, and/or a reliability of the semiconductor package may be increased, when compared to a related semiconductor package.

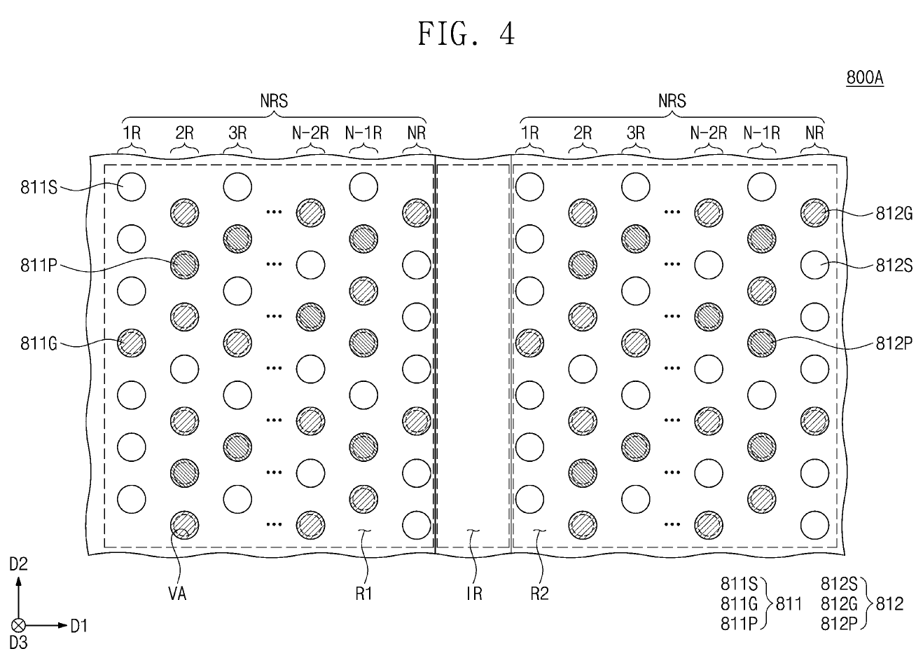

FIG. 4 is a plan view illustrating a top surface of a connection substrate, according to an embodiment of the present disclosure. Referring to FIGS. 1 and 4, the connection substrate 800 may include a first region R1, a second region R2, a third region R3, and a fourth region R4. Each of the first to fourth regions R1 to R4 may be a region on which the plurality of substrate pads 810 are disposed. The first region R1 and the second region R2 may be spaced apart from each other in the first direction D1. A signal line region IR may be interposed between the first region R1 and the second region R2. Similarly, the signal line region IR may be interposed between the second region R2 and the third region R3 and between the third region R3 and the fourth region R4.

The plurality of substrate pads 810 may include a plurality of first substrate pads 811, a plurality of second substrate pads 812, a plurality of third substrate pads 813, and a plurality of fourth substrate pads 814. The plurality of first substrate pads 811 may be overlapped with the plurality of first chip pads 110 in the third direction D3, the plurality of second substrate pads 812 may be overlapped with the plurality of second chip pads 210 in the third direction D3, the plurality of third substrate pads 813 may be overlapped with the plurality of third chip pads 310 in the third direction D3, and the plurality of fourth substrate pads 814 may be overlapped with the plurality of fourth chip pads 410 in the third direction D3.

The pluralities of first to fourth substrate pads 811 to 814 may be electrically connected to the pluralities of first to fourth chip pads 110 to 410 through the pluralities of first to fourth vertical conductive structures 710 to 740. The pluralities of first to fourth substrate pads 811 to 814 may be disposed in a substantially similar and/or the same manner as the pluralities of first to fourth chip pads 110 to 410 described with reference to FIG. 3. That is, the pluralities of first to fourth substrate pads 811 to 814 may be placed to form N columns NRS arranged in the first direction D1. The plurality of first substrate pads 811 may include a plurality of first substrate power pads 811P, a plurality of first substrate ground pads 811G, and a plurality of first substrate signal pads 811S. The plurality of second substrate pads 812 may include a plurality of second substrate power pads 812P, a plurality of second substrate ground pads 812G, and a plurality of second substrate signal pads 812S.

The pluralities of third substrate pads 813 and the fourth substrate pads 814 may also include pluralities of substrate power pads, pluralities of substrate ground pads, and pluralities of substrate signal pads. The pluralities of substrate power pads, the pluralities of substrate ground pads, and the pluralities of substrate signal pads may be determined depending on the types of the plurality of vertical conductive structures 700 and the pluralities of first to fourth chip pads 110 to 410 connected thereto.

The plurality of first substrate power pads 811P, the plurality of first substrate ground pads 811G, the plurality of second substrate power pads 812P, and the plurality of second substrate ground pads 812G may be connected to pads in different layers through a via VA, as shown in FIG. 4. At least one of the plurality of first substrate signal pads 811S in the N-th column and the plurality of second substrate signal pads 812S in the first column 1R may be connected to signal lines passing through the signal line region IR of the same layer. Alternatively or additionally, at least one of the plurality of first substrate signal pads 811S in the N-th column and the plurality of second substrate signal pads 812S in the first column 1R may be connected to pads in different layers through the via VA and may be connected to signal lines, which may be connected to the pads and may be provided to penetrate the signal line region IR. That is, the plurality of first substrate signal pads 811S in the N-th column and the plurality of second substrate signal pads 812S in the first column 1R may be electrically connected to the signal lines passing through the signal line region IR.

According to an embodiment of the present disclosure, many of the plurality of first substrate signal pads 811S may be disposed in the N-th column of the first region R1, many of the plurality of second substrate signal pads 812S may be disposed in the first column of the second region R2, and the signal line region IR may be disposed therebetween. The signal lines may be disposed in the signal line region IR to connect the first and second substrate signal pads 811S and 812S, which may be placed at both sides thereof, to each other. In such embodiments, it may be possible to reduce the length of signal lines and/or decrease the density of signal lines, and as such, may suppress and/or reduce a likelihood of cross-talk issue, when compared to related semiconductor packages.

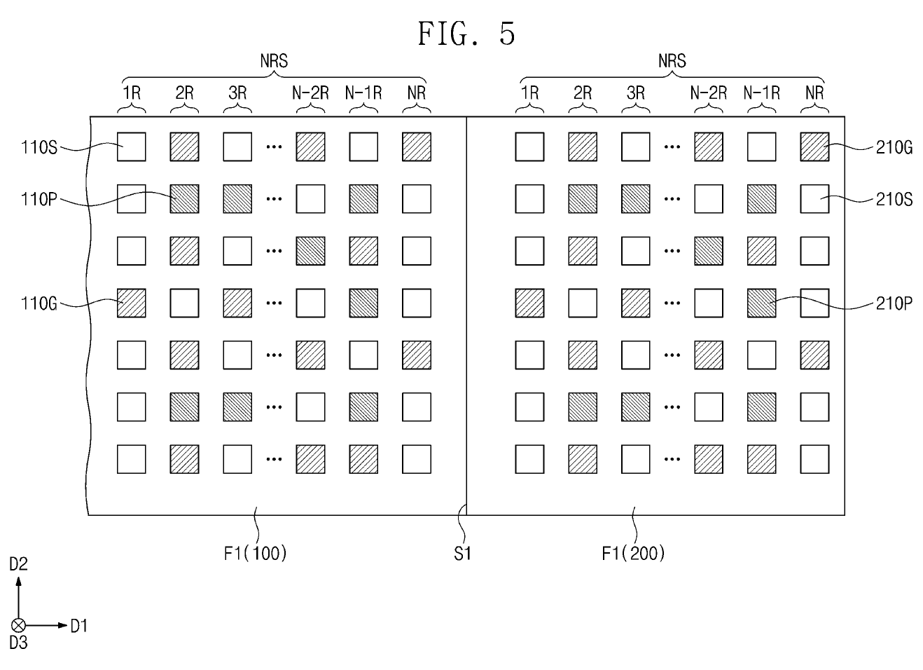

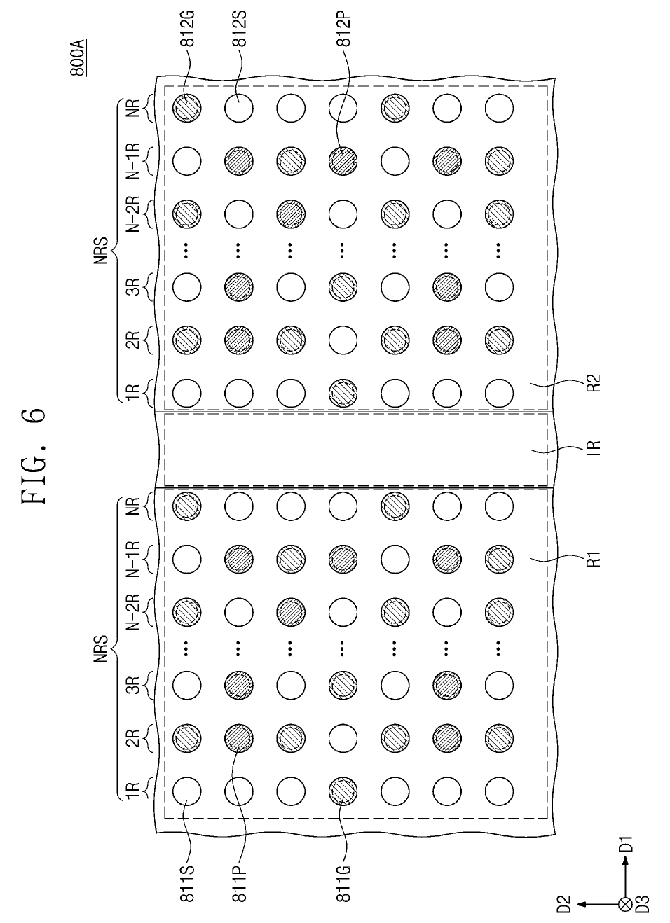

FIG. 5 is a plan view illustrating active surfaces of the first and second semiconductor chips, according to an embodiment of the present disclosure. FIG. 6 is a plan view illustrating a top surface of a connection substrate, according to an embodiment of the present disclosure.

Except for features to be described below, the semiconductor package, according to the present embodiment, may have substantially the same features as those described with reference to FIGS. 1 to 4, and thus, an overlapping description thereof may be omitted for the sake of brevity.

Referring to FIG. 5, the plurality of first chip pads 110 and the plurality of second chip pads 210 may be arranged in the first direction D1 and in a lattice shape. The plurality of first chip pads 110 in the adjacent columns may be aligned to each other in the second direction D2. The plurality of second chip pads 210 in adjacent columns may be aligned to each other in the second direction D2. Referring to FIG. 6, the plurality of first substrate pads 811 and the plurality of second substrate pads 812 may be arranged in the first direction D1 and in a lattice shape. The plurality of first substrate pads 811 in adjacent columns may be aligned to each other in the second direction D2. The plurality of second substrate pads 812 in adjacent columns may be aligned to each other in the second direction D2.

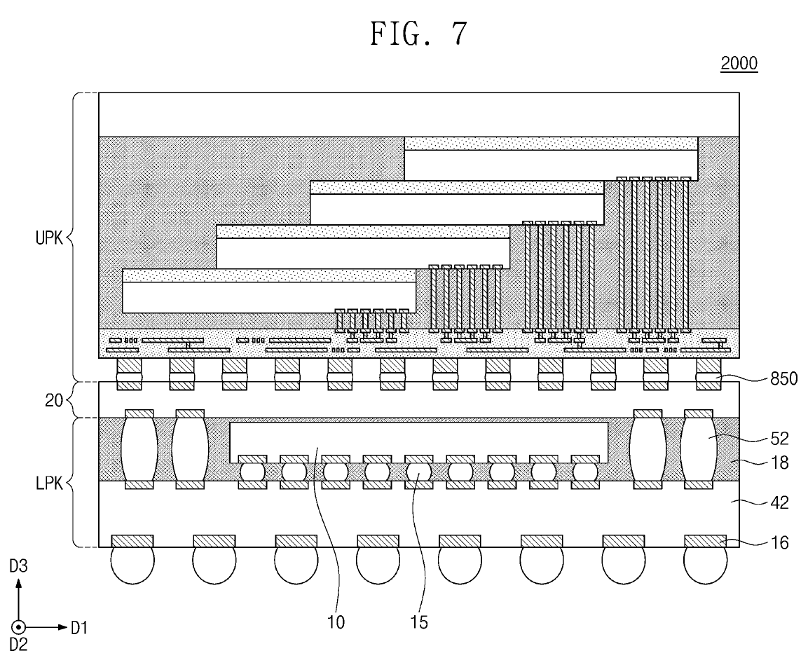

FIG. 7 is a sectional view illustrating a semiconductor package, according to an embodiment of the present disclosure.

Referring to FIG. 7, a semiconductor package 2000 may correspond to an example of a package-on-package. As shown in FIG. 7, the semiconductor package 2000 may include a lower semiconductor package LPK, an upper semiconductor package UPK on the lower semiconductor package LPK, and an interposer 20 interposed therebetween. The upper semiconductor package UPK may be substantially similar and/or the same as the semiconductor package 1000 described with reference to FIG. 1.

The lower semiconductor package LPK may include a lower package substrate 42 and a lower semiconductor chip 10 mounted thereon. In the package-on-package structure, the plurality of first to fourth semiconductor chips 100 to 400 of the upper semiconductor package UPK may be referred to as the plurality of first to fourth upper semiconductor chips 100 to 400. For example, the lower semiconductor chip 10 may be and/or may include a logic chip, and the plurality of first to fourth upper semiconductor chips 100 to 400 may be and/or may include memory chips. The lower semiconductor chip 10 and the plurality of first to fourth upper semiconductor chips 100 to 400 may include semiconductor chips of different kinds from each other.

The lower package substrate 42 may be a printed circuit board (PCB), which may include an interconnection structure and may have a single-layered or a multi-layered structure. The lower semiconductor chip 10 may be mounted on the lower package substrate 42 by an inner connection terminal 15 in a flip-chip bonding manner. An outer connection terminal 16 may be attached to the lower package substrate 42. The inner connection terminal 15 and the outer connection terminal 16 may include at least one of copper bumps, solder layers, and solder balls. A top surface of the lower package substrate 42 and the lower semiconductor chip 10 may be covered with a lower mold layer 18. The lower mold layer 18 may be formed of and/or may include an insulating resin (e.g., an epoxy molding compound (EMC)).

The upper semiconductor package UPK may be connected to the interposer 20 by the connection terminal 850. The interposer 20 may be electrically connected to the lower semiconductor package LPK through a package connection element 52. The package connection element 52 may include at least one of conductive bumps, conductive pillars, solder layers, or solder balls. In an embodiment, an opening, in which the package connection element 52 is inserted, may be formed in the lower mold layer 18.

FIGS. 8 to 10 are sectional views illustrating a process of fabricating a semiconductor package, according to an embodiment of the present disclosure.

Referring to FIG. 8, the semiconductor chip stack CS may be formed on the supporting substrate 600. The formation of the semiconductor chip stack CS may include stacking the plurality of first to fourth semiconductor chips 100 to 400 in an offset manner. For example, the formation of the semiconductor chip stack CS may include attaching the a fourth adhesive layer of the plurality of adhesive layers AD, which may be attached to the fourth upper surface F2 of the fourth semiconductor chip 400, to the top surface of the supporting substrate 600 and attaching a third adhesive layer of the plurality of adhesive layers AD, which may be attached to the third upper surface F2 of the third semiconductor chip 300, to the fourth lower surface F1 of the fourth semiconductor chip 400. As shown in FIG. 8, the attachment position of the third semiconductor chip 300 may be adjusted in such a way that the plurality of fourth chip pads 410 on the fourth lower surface F1 of the fourth semiconductor chip 400 may be exposed from the third adhesive layer of the plurality of adhesive layers AD on the third upper surface F2 of the third semiconductor chip 300.

The second semiconductor chip 200 may be attached to the third semiconductor chip 300 in a substantially similar and/or the same manner of attaching the third semiconductor chip 300 to the fourth semiconductor chip 400, and subsequently, the first semiconductor chip 100 may also be attached to the second semiconductor chip 200 in a substantially similar and/or the same manner.

The plurality of vertical conductive structures 700 may be formed on the pluralities of first to fourth chip pads 110 to 410, respectively. The plurality of vertical conductive structures 700 may be formed through, for example, a metal wire bonding process. In an embodiment, the metal wire bonding process may include coupling a capillary to the metal wire, placing the metal wire on the pluralities of first to fourth chip pads 110 to 410, lowering the capillary to attach one end of the metal wire to the pluralities of first to fourth chip pads 110 to 410, elevating the capillary to stretch the metal wire in a vertical direction, and cutting the metal wire. However, the present disclosure is not limited in this regard, and other processes may be used to form the plurality of vertical conductive structures 700 without departing from the scope of the present disclosure.

In an embodiment, the formation of the plurality of vertical conductive structures 700 may include forming a seed layer on the lower surface F1 of each semiconductor chip of the plurality of first to fourth semiconductor chips 100 to 400, and forming a metal pillar through an electroplating process, and patterning the seed layer.

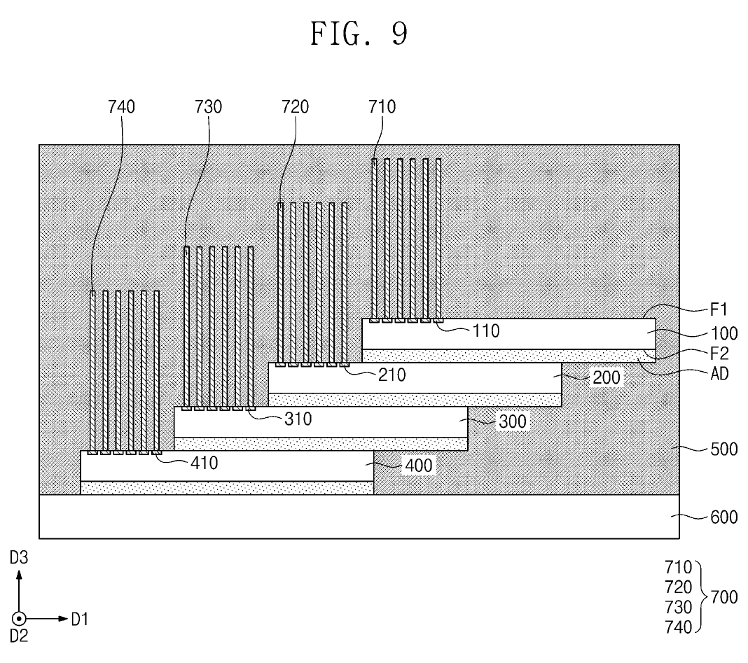

Referring to FIG. 9, the mold layer 500 may be formed to cover the top surface of the supporting substrate 600, the exposed lower surfaces F1 and the side surfaces of the plurality of first to fourth semiconductor chips 100 to 400, and the plurality of vertical conductive structures 700 and to fill a space between them.

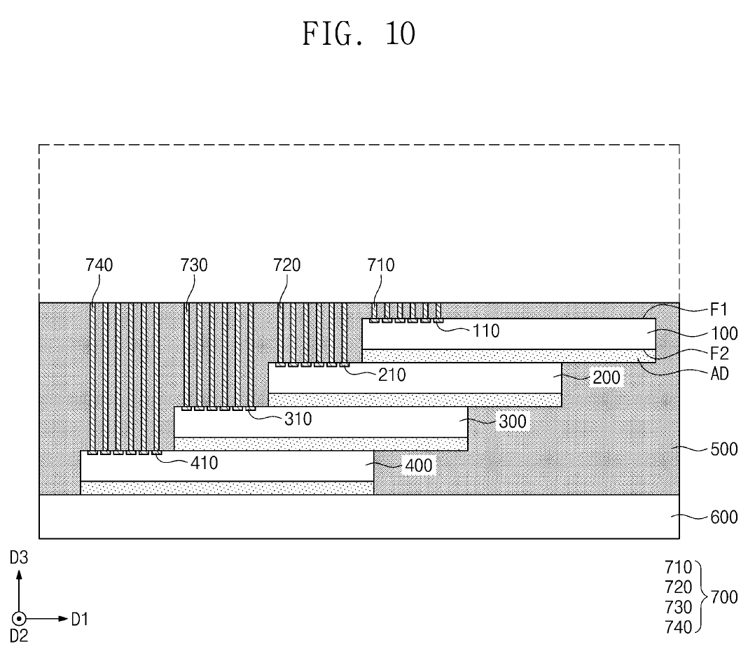

Referring to FIG. 10, a grinding process may be performed on a surface of the mold layer 500 to expose top surfaces of the plurality of vertical conductive structures 700 to the outside. As a result of the grinding process, the plurality of vertical conductive structures 700 may be formed to have top surfaces that are located at a substantially similar and/or the same level. The top surface of the mold layer 500 and the top surfaces of the plurality of vertical conductive structures 700 may be substantially coplanar with each other.

Referring back to FIG. 1, the connection substrate 800 may be formed on the mold layer 500. The formation of the connection substrate 800 may include forming the insulating layer 840 and forming the redistribution pattern 820. The formation of the insulating layer 840 may include coating, exposing, developing, and curing a photoimageable insulating material on the mold layer 500. The formation of the redistribution pattern 820 may include forming a seed layer, forming a photomask pattern to expose a portion of the seed layer, forming a conductive pattern on the exposed seed layer, removing the photomask pattern, and etching the seed layer using the conductive pattern as a mask to form the seed pattern. The upper pad 810 and the lower pad 830 may be formed by a substantially similar and/or the same method as that for the redistribution pattern 820. The semiconductor package 1000 may be formed by forming the connection terminal 850 on the lower pad 830.

According to an embodiment of the present disclosure, a semiconductor package may include a first semiconductor chip and a second semiconductor chip, which are stacked in an offset manner, and the first and second semiconductor chips may be electrically connected to a connection substrate through a vertical conductive structure. The first and second semiconductor chips may be configured such that chip signal pads are concentrated in the first and last columns of each chip. In this case, it may be possible to reduce a cross-talk issue between the vertical conductive structures connected to the chip signal pads and to improve the reliability of the semiconductor package, when compared to the case where the chip signal pads are disposed in an inner column.

While example embodiments of the present disclosure have been particularly shown and described, it is to be understood by one of ordinary skill in the art that variations in form and detail may be made therein without departing from the spirit and scope of the attached claims.

What is claimed is:

1. A semiconductor package, comprising:
a substrate;
a first semiconductor chip on the substrate; and
a second semiconductor chip on the first semiconductor chip,
wherein the second semiconductor chip is offset from the first semiconductor chip in a first direction parallel to a top surface of the substrate,
wherein the first semiconductor chip comprises a plurality of first chip pads disposed to form a plurality of first columns,
wherein a first edge column of the plurality of first columns is adjacent to a first side surface of the first semiconductor chip and to a previous column of the plurality of first columns,
wherein the second semiconductor chip comprises a plurality of second chip pads disposed to form a plurality of second columns,
wherein a second edge column of the plurality of second columns is adjacent to the first side surface of the first semiconductor chip and to a next column of the plurality of second columns,
wherein one or more first chip pads of the first edge column and the previous column comprise a plurality of first chip signal pads,
wherein one or more second chip pads of the second edge column and the next column comprise a plurality of second chip signal pads,
wherein a first number of first chip signal pads of the first edge column is greater than a second number of first chip signal pads of the previous column, and
wherein a third number of second chip signal pads of the second edge column is greater than a fourth number of second chip signal pads of the next column.

2. The semiconductor package of claim 1, further comprising:
a plurality of first vertical conductive structures disposed between the plurality of first chip pads and the substrate; and
a plurality of second vertical conductive structures between the plurality of second chip pads and the substrate.

3. The semiconductor package of claim 2, wherein each vertical conductive structure of the plurality of first vertical conductive structures and the plurality of second vertical conductive structures comprises a metal wire.

4. The semiconductor package of claim 2, wherein each vertical conductive structure of the plurality of first vertical conductive structures and the plurality of second vertical conductive structures comprises a seed pattern and a metal pillar on the seed pattern, and
wherein the metal pillar comprises copper (Cu).

5. The semiconductor package of claim 2, wherein the substrate comprises a polymer insulating layer and an interconnection structure in the polymer insulating layer,
wherein the semiconductor package further comprises a mold layer on the substrate,
wherein the mold layer at least partially covers the first semiconductor chip and the second semiconductor chip, and
wherein the mold layer at least partially covers side surfaces of the plurality of first vertical conductive structures and side surfaces of the plurality of second vertical conductive structures.

6. The semiconductor package of claim 1, wherein a first pitch between the plurality of first chip pads in the first edge column and the previous column is smaller than a second pitch between the plurality of first chip pads in the first edge column and the plurality of second chip pads in the second edge column.

7. The semiconductor package of claim 6, wherein the second pitch is more than twice as large as the first pitch.

8. The semiconductor package of claim 1, wherein the plurality of first chip pads in each of the first edge column and the previous column further comprise a plurality of first chip ground pads,
wherein the plurality of second chip pads in each of the second edge column and the next column further comprise a plurality of second chip ground pads,
wherein a fifth number of first chip ground pads in the first edge column is less than a sixth number of first chip ground pads in the previous column, and
wherein a seventh number of second chip ground pads in the second edge column is less than an eighth number of second chip ground pads in the next column.

9. The semiconductor package of claim 1, wherein the substrate comprises:
a first region provided with first substrate pads;
a second region provided with second substrate pads; and
a signal line region therebetween,
wherein the plurality of first chip pads at least partially overlap the first substrate pads in a third direction perpendicular to the top surface of the substrate,
wherein the plurality of second chip pads at least partially overlap the second substrate pads in the third direction, and
wherein the first region and the second region are spaced apart from each other in the first direction.

10. The semiconductor package of claim 9, wherein the first substrate pads comprise first substrate signal pads,
wherein the first chip signal pads of the first edge column at least partially overlap the first substrate signal pads in the third direction,
wherein the second region comprises second substrate signal pads,
wherein the second chip signal pads of the second edge column at least partially overlap the second substrate signal pads in the third direction, and
wherein the signal line region comprises signal lines coupled with the first substrate signal pads and the second substrate signal pads, respectively.

11. A semiconductor package, comprising:
a substrate;
a first semiconductor chip on the substrate;
a second semiconductor chip on the first semiconductor chip and offset from the first semiconductor chip in a first direction parallel to a top surface of the substrate;
a plurality of first vertical conductive structures between the first semiconductor chip and the substrate; and
a plurality of second vertical conductive structures between the second semiconductor chip and the substrate,
wherein the first semiconductor chip comprises a plurality of first chip pads, disposed in the first direction to form a plurality of N first columns, N being a positive integer greater than one,
wherein the second semiconductor chip comprises a plurality of second chip pads, disposed in the first direction to form a plurality of N second columns,
wherein each of a first column and an N-th column of the plurality of N first columns comprises a first number of chip signal pads that is greater than a second number of first chip pads comprised by each of remaining second to (N–1)-th columns of the plurality of N first columns,
wherein each of a first column and an N-th column of the plurality of N second columns comprises a third number of chip signal pads that is greater than a fourth number of second chip pads comprised by each of remaining second to (N–1)-th columns of the plurality of N second columns,
wherein the plurality of first vertical conductive structures are coupled with the plurality of first chip pads, respectively, and
wherein the plurality of second vertical conductive structures are coupled with the plurality of second chip pads, respectively.

12. The semiconductor package of claim 11, wherein the plurality of first chip pads and the plurality of second chip pads are disposed in the first direction to form a zigzag arrangement,
wherein each chip pad in each column of the plurality of N first columns is disposed at a first position that is offset from an adjacent chip pad of an adjacent column of the plurality of N first columns, and
wherein each chip pad in each column of the plurality of N second columns is disposed at a second position that is offset from an adjacent chip pad of an adjacent column of the plurality of N second columns.

13. The semiconductor package of claim 11, wherein the plurality of first chip pads and the plurality of second chip pads are disposed in the first direction to form a lattice arrangement,
wherein each chip pad in each column of the plurality of N first columns is aligned to a corresponding chip pad in an adjacent column of the plurality of N first columns in a second direction, the second direction being parallel to the top surface of the substrate and perpendicular to the first direction, and
wherein each chip pad in each column of the plurality of N second columns is aligned to a corresponding chip pad in an adjacent column of the plurality of N first columns in the second direction.

14. The semiconductor package of claim 11, wherein the plurality of first vertical conductive structures are disposed in the first direction by a first distance, and
wherein a second distance between at least one of the plurality of first vertical conductive structures in the N-th column and at least one of the plurality of second vertical conductive structures in the first column is greater than the first distance.

15. The semiconductor package of claim 14, wherein the second distance is greater than two times the first distance.

16. The semiconductor package of claim 11, wherein each of a second column and an (N–1)-th column of the plurality of N first columns comprises a fifth number of chip ground pads that is greater than a sixth number of chip ground pads comprised by each of remaining third to (N–2)-th columns of the plurality of N first columns.

17. A semiconductor package, comprising:
a first semiconductor package; and
a second semiconductor package on the first semiconductor package,
wherein the second semiconductor package comprises:
a connection substrate;
a semiconductor chip stack vertically spaced apart from the connection substrate;
a plurality of vertical conductive structures between the semiconductor chip stack and the connection substrate; and
a mold layer at least partially covering the connection substrate, the semiconductor chip stack, and the plurality of vertical conductive structures,
wherein the semiconductor chip stack comprises a plurality of semiconductor chips stacked in an offset manner, in a first direction parallel to a top surface of the connection substrate,
wherein each of the plurality of semiconductor chips comprises a plurality of chip pads coupled with the plurality of vertical conductive structures,
wherein the plurality of chip pads comprises a plurality of chip signal pads,
wherein the plurality of chip pads are disposed in the first direction to form a plurality of N columns, N being a positive integer greater than one,
wherein a number of chip signal pads in a first column of the plurality of N columns is greater than a number of chip signal pads in a second column of the plurality of N columns, and
wherein a number of chip signal pads in an N-th column of the plurality of N columns is greater than a number of chip signal pads in an (N–1)-th column of the plurality of N columns.

18. The semiconductor package of claim 17, wherein the plurality of chip pads further comprise a plurality of chip ground pads,
wherein a number of chip ground pads in the second column of the plurality of N columns is greater than a number of chip ground pads in the first column of the plurality of N columns, and
wherein a number of chip ground pads in the (N–1)-th column of the plurality of N columns is greater than a number of the chip ground pads in the N-th column of the plurality of N columns .

19. The semiconductor package of claim 17, wherein each of the number of the chip signal pads in the first column of the plurality of N columns and the number of the chip signal pads in the N-th column is greater than the number of the chip signal pads in each of the second column to the (N-1)-th columns of the plurality of N columns.

20. The semiconductor package of claim 17, wherein the connection substrate comprises a redistribution substrate,
wherein the semiconductor package further comprises a supporting substrate on the connection substrate, and
wherein the supporting substrate is vertically spaced apart from the connection substrate with the semiconductor chip stack interposed therebetween.
